(19) United States
(12) Patent Application Publication
(10) Pub. No.: US 2007/0272948 A1
(43) Pub. Date: Nov. 29, 2007

(54) INVERTER WITH DUAL-GATE ORGANIC THIN-FILM TRANSISTOR

(76) Inventors: Jae Bon KOO, Daejeon (KR); Seong Hyun KIM, Daejeon (KR); Kyung Soo SUH, Daejeon (KR); Sang Chul LIM, Daejeon (KR); Jung Hun LEE, Daejeon (KR); Chan Hoe KU, Gyeonggi (KR)

Correspondence Address: LADAS & PARRY LLP, 224 SOUTH MICHIGAN AVENUE, SUITE 1600, CHICAGO, IL, 60604, US

(21) Appl. No.: 11/693,830

(22) Filed: Mar. 30, 2007

(30) Foreign Application Priority Data
May 26, 2006 (KR) 2006-47388

(51) Int. Cl. H01L 27/10; H01L 29/76

(52) U.S. Cl. 257/206; 257/391; 257/E27.064

(57) ABSTRACT

Provided is an inverter having a new structure capable of easily controlling a threshold voltage according to position in fabricating an inverter circuit on a plastic substrate using an organic semiconductor. A driver transistor is formed with a dual-gate structure and a positive bias voltage is applied to the top gate of the driver transistor so that a body effect appears in the organic semiconductor. Accordingly, the threshold voltage is shifted to a negative zone due to positive potential applied to the top gate of the driver transistor so that the driver transistor acts as an enhancement type transistor. A dual-gate organic structure may be applied to a load transistor rather than the driver transistor, or a p-type dual-gate organic transistor structure may be applied to both the driver transistor and the load transistor. Lifespan of the device can be increased, reliability of the device can be improved, and an organic inverter can be provided in which characteristics of organic electronic elements are easily adjusted according to circuit design even after the organic electronic elements are fabricated.

### CROSS-REFERENCE TO RELATED APPLICATION

This application claims priority to and the benefit of Korean Patent Application No. 2006-0047388, filed May 26, 2006, the disclosure of which is incorporated herein by reference in its entirety.

### BACKGROUND

1. Field of the Invention

The present invention relates to an inverter using an organic semiconductor, and more particularly, to an inverter implemented with a dual-gate organic transistor on a plastic substrate.

2. Discussion of Related Art

Organic thin-film transistors have the advantage of being more easily fabricated at a lower temperature than conventional silicon transistors, which makes it possible to fabricate an organic thin-film transistor on a flexible plastic substrate. Accordingly, organic thin-film transistors have come into the spotlight as next-generation devices. An organic thin-film transistor is used as a pixel driving switch for a flexible display device or in a radio frequency identification (RFID) circuit, for example. When the organic thin-film transistor is used as a pixel driving switch for a display device, it is sufficiently implemented with only a single-type transistor, i.e., a p-type transistor. However, for a circuit, it is desirable to use a CMOS transistor, which is a combination of a p-type transistor and an n-type transistor, in view of power consumption and speed.

However, since an n-type organic semiconductor device lacks stability and reliability, only a p-type transistor is commonly used to form an inverter.

FIGS. 1a and 1b illustrate two conventional inverter circuits that can be fabricated with only a p-type transistor. The inverter shown in FIG. 1a has a depletion type transistor as a load and an enhancement type transistor as a driver, and the inverter shown in FIG. 1b has enhancement type transistors as a load and a driver. The former is commonly known as a D-inverter or a zero driver load logic inverter, and the latter as an E-inverter or a diode-connected load logic inverter.

Referring to FIGS. 1a and 1b, the D-inverter is superior to the E-inverter in terms of power consumption and gain. Threshold voltage in an organic semiconductor cannot be controlled by doping, unlike a conventional silicon semiconductor. In other words, it is difficult to fabricate a D-inverter through a conventional semiconductor fabrication process because organic transistors with a different threshold voltage cannot be formed on the same substrate. In order to implement a D-inverter, transistors must be formed with a different threshold voltage after surface processing their respective regions differently. Particularly, an organic semiconductor has poor uniformity on a substrate, making it difficult to fabricate a stable inverter.

In implementing a D-inverter using current technology, a depletion type transistor for a load is formed to have a large width/length (W/L) ratio, and an enhancement type transistor for a driver is formed to have a small W/L ratio in order to accomplish current adjustment.

As described above, in the conventional method for fabricating a D-inverter, a transistor with a large W/L ratio is used as a depletion type load since high current flows when a gate voltage V_{G} is 0V, and a transistor with a small W/L ratio is used as an enhancement type driver. Thus, in order to obtain an optimal condition, an inverter needs to be designed and fabricated after all features of transistors are secured and obtained for each W/L ratio.

### SUMMARY OF THE INVENTION

The present invention greatly improves and enhances a previous conventional method employing a W/L ratio of transistors in fabricating an inverter having a depletion type load and an enhancement type driver. The present invention is directed to an inverter structure in which a driver transistor is implemented as an enhancement type transistor by using a dual-gate organic transistor.

The present invention is also directed to an inverter structure implemented by applying a p-type dual-gate organic transistor structure to a load transistor rather than a driver transistor, or by applying a p-type dual-gate organic transistor structure to both a driver transistor and a load transistor.

One aspect of the present invention provides an inverter comprising: a load transistor; and a driver transistor connected to the load transistor and having a dual-gate structure and an organic channel.

The load transistor may use a first dielectric layer or a second dielectric layer as a gate insulating layer.

Another aspect of the present invention provides an inverter comprising: a load transistor having a dual-gate structure and an organic channel; and a driver transistor connected to the load transistor.

The driver transistor may use the first dielectric layer or the second dielectric layer as a gate insulating layer.

Yet another aspect of the present invention provides an inverter comprising: a load transistor having a dual-gate structure and an organic channel; and a driver transistor having a dual-gate stricture and an organic channel and connected to the load transistor.

Each of the load transistor and the driver transistor may comprise a bottom gate electrode facing the organic channel with a first dielectric layer interposed therebetween; a top gate electrode facing the organic channel with a second dielectric layer interposed therebetween; and source and drain electrodes connected to the organic channel, and a positive bias voltage may be applied to the top gate electrode of the driver transistor, and a negative bias voltage may be applied to the top gate electrode of the load transistor.

The driver transistor and the load transistor may have the same W/L ratio.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1a is a circuit diagram illustrating an example of a structure of a conventional inverter that can be fabricated with only a p-type transistor;

FIG. 1b is a circuit diagram illustrating another example of a structure of a conventional inverter that can be fabricated with only a p-type transistor;

FIGS. 2a and 2b are cross-sectional views illustrating a structure of an inverter having a p-type organic thin-film transistor (OTFT) according to an exemplary embodiment of the present invention;

FIGS. 3a and 3b are cross-sectional views illustrating a structure of an inverter having a p-type organic thin-film transistor according to another exemplary embodiment of the present invention;

FIGS. 4a and 4b are cross-sectional views illustrating a structure of an inverter having a p-type organic thin-film transistor according to yet another exemplary embodiment of the present invention;

FIGS. 5a and 5b are graphs showing a transfer curve of a dual-gate organic thin-film transistor whose threshold voltage varies with top gate bias voltage according to the present invention; and

FIG. 6 illustrates a circuit of a D-inverter fabricated with a dual-gate organic transistor and its voltage transfer characteristic according to an exemplary embodiment of the present invention.

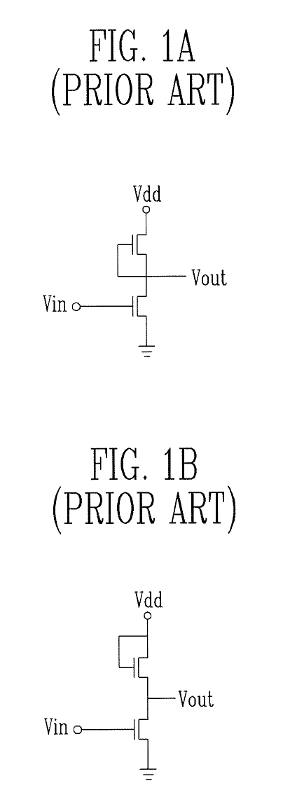

### DETAILED DESCRIPTION OF EXEMPLARY EMBODIMENTS

Hereinafter, exemplary embodiments of the present invention will be described in detail. However, the present invention is not limited to the exemplary embodiments disclosed below, but can be implemented in various forms. Therefore, the present exemplary embodiment is provided for complete disclosure of the present invention and to fully inform the scope of the present invention to those of ordinary skill in the art.

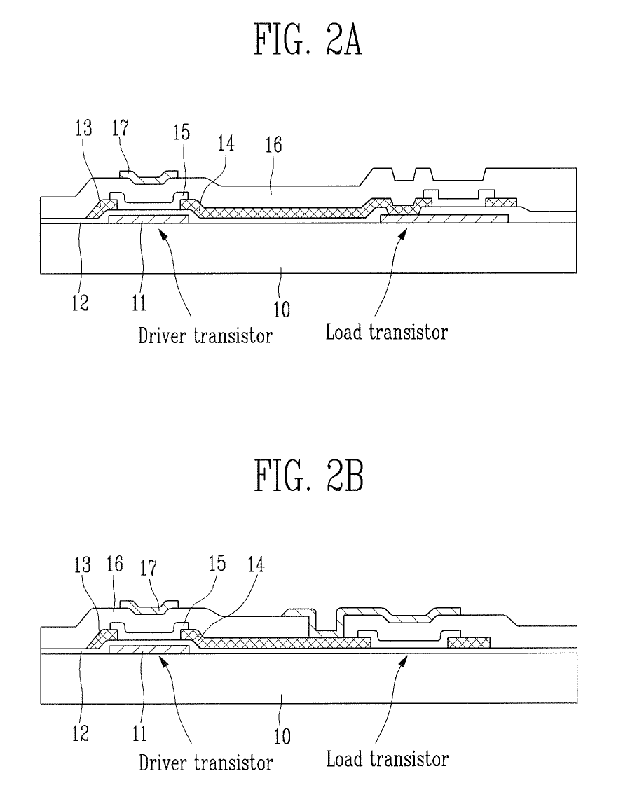

FIGS. 2a and 2b are cross-sectional views illustrating a structure of an inverter having a p-type organic thin-film transistor (OTFT) according to an exemplary embodiment of the present invention.

Referring to FIGS. 2a and 2b, an inverter according to the exemplary embodiment includes a load transistor having an organic transistor structure, and a driver transistor connected to the load transistor and having a dual-gate organic transistor structure. Here, when the inverter is a D-inverter, the load transistor has a gate and a source connected to each other, and when the inverter is an E-inverter, the load transistor has a gate and a drain connected to each other.

The driver transistor includes a bottom gate electrode 11 located on a substrate 10, a first dielectric layer 12 covering the substrate 10 having the bottom gate electrode 11, an organic semiconductor layer 15 formed facing the bottom gate electrode 11 and constituting an organic channel, source/drain electrodes 13 and 14 connected to both ends of the organic semiconductor layer 15, a second dielectric layer 16 covering the structure, and a top gate electrode 17 formed facing the organic semiconductor layer 15 with the second dielectric layer 16 interposed therebetween. Here, the bottom gate electrode 11 of the driver transistor is located beneath the organic transistor structure, and the top gate electrode 17 is located on the organic transistor structure. In the inverter shown in FIG. 2a, the load transistor uses the first dielectric layer 12 of the driver transistor as a gate insulating layer. In the inverter shown in FIG. 2b, the load transistor uses the second dielectric layer 16 of the driver transistor as a gate insulating layer.

A process of fabricating the organic transistor having a dual-gate structure will be briefly described. Ti is deposited to a 50 nm thickness on the organic substrate 10, Corning 1737, using an e-beam deposition method to form the bottom gate electrode 11. Plasma Enhanced Atomic Layer Deposition (PEALD) Al₂O₃ is coated to a 150 nm thickness using an O₂ gas containing a trimethyl aluminum (TMA) precursor and an N₂ gas to form the first dielectric layer 12. By using the PEALD Al₂O₃, a breakdown field of 9MV/cm and a dielectric capacitance Cox of 41 nF/cm² can be obtained. A Ti layer and an Au layer are then deposited to a 3 nm thickness and an 80 nm thickness on the first dielectric layer 12 to form the source/drain electrodes 13 and 14, respectively. The substrate having the structure is treated with hexamethyldisilazane (HMDS) as a self-organizing material in order to improve the quality of an organic/dielectric interface, and then is coated with an organic material of a 60 nm thickness to form the organic semiconductor layer 15. A parylene layer is then formed as the second dielectric layer 16 to a 300 nm thickness on the substrate having the bottom gate organic transistor structure. By using the parylene layer, a dielectric capacitance Cpar of 7.15 nF/cm² can be obtained. Finally, a Ti layer is deposited to a 50 nm thickness, forming the top gate electrode 17. Patterning for integration may be accomplished by depositing each of the layers using a shadow mask or photolithography.

Operation of the inverter will be briefly described. If the inverter is a D-inverter, a threshold voltage of the driver transistor shifts from a positive zone to a negative zone when an input voltage is applied to the bottom gate electrode 11 and a positive voltage is applied to the top gate electrode 17. If the inverter is an E-inverter, a positive bias voltage is applied to top gate electrodes of the load transistor and the driver transistor because each of the load transistor and the driver transistor needs to operate as an enhancement transistor. In this manner, it is possible to easily implement an inverter by using organic transistors having the same W/L ratio.

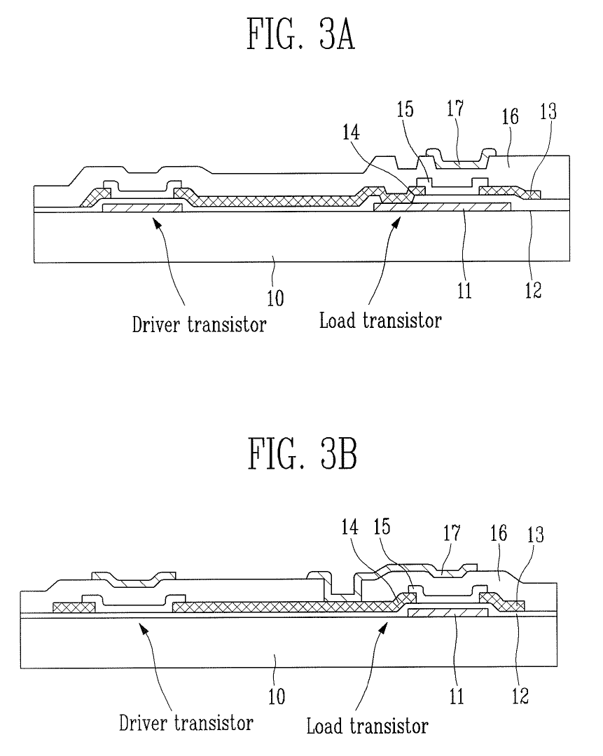

FIGS. 3a and 3b are cross-sectional views illustrating a structure of an inverter having a p-type organic thin-film transistor according to another exemplary embodiment of the present invention.

Referring to FIGS. 3a and 3b, an inverter according to this exemplary embodiment includes a load transistor having a dual-gate organic transistor structure, and a driver transistor connected to the load transistor.

In this exemplary embodiment, the inverter is substantially the same as the inverter of the previously-described exemplary embodiment except that the load transistor, rather than the driver transistor, has a dual-gate organic transistor structure.

In the inverter of this exemplary embodiment, a negative bias voltage is applied to a top gate of the load transistor to simultaneously switch the bottom and top transistors on. This shifts a threshold voltage of the load transistor to a positive zone and the load transistor becomes a depletion type transistor, thereby improving characteristics of the inverter. In this manner, it is possible to easily implement the D-inverter by using organic transistors having the same W/L ratio.

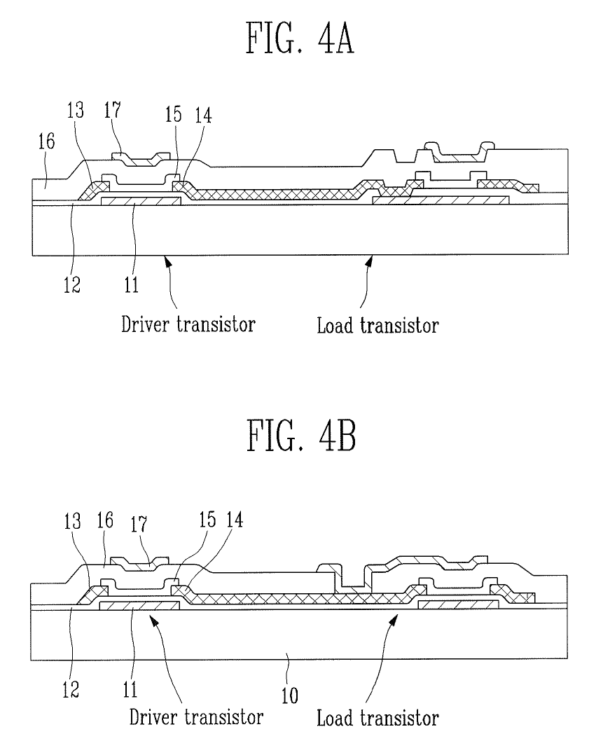

FIGS. 4a and 4b are cross-sectional views illustrating a structure of an inverter having a p-type organic thin-film transistor according to another exemplary embodiment of the present invention.

Referring to FIGS. 4a and 4b, an inverter according to this exemplary embodiment includes a load transistor having a dual-gate organic transistor structure, and a driver transistor connected to the load transistor and having a dual-gate organic transistor structure.

In the inverter of this exemplary embodiment, both the driver transistor and the load transistor have a dual-gate organic transistor structure. In operation of the inverter, a positive voltage is applied to a top gate electrode of the driver transistor and a negative voltage is applied to the top gate electrode of the load transistor. In this manner, it is possible to easily implement a D-inverter by using organic transistors having the same W/L ratio.

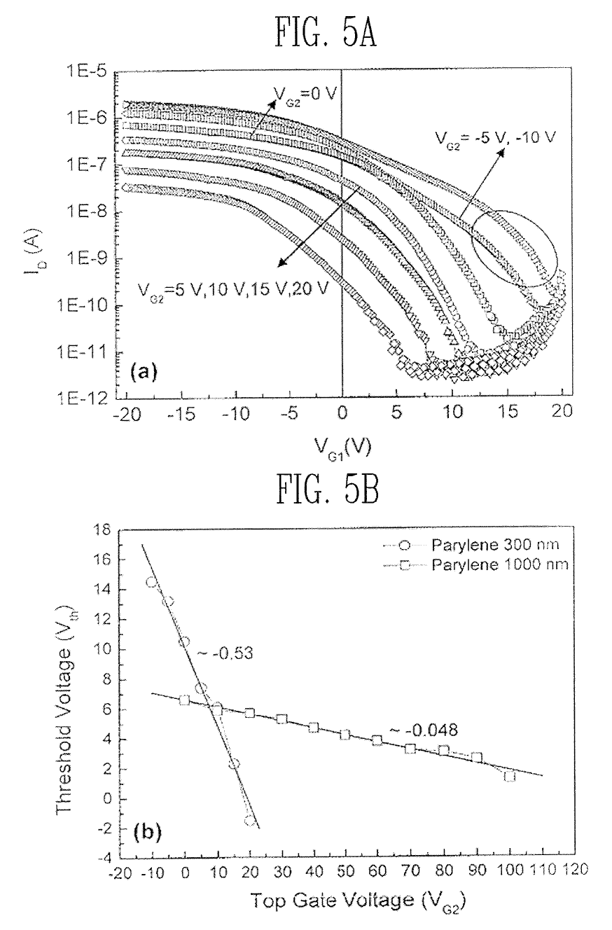

FIGS. 5a and 5b are graphs showing a transfer curve of a dual-gate organic thin-film transistor whose threshold voltage varies with top gate bias voltage according to the present invention.

Referring to FIG. 5a, in an inverter according to this exemplary embodiment, when a bottom gate bias voltage V_{G1} is 0V and a top gate bias voltage V_{G2} is changed from −10V to 20V in steps of 5V, a threshold voltage Vₜₕ regularly changed from 14.5V to −1.5V. When the top gate bias voltage was negative, lump/hill shapes were observed as indicated by a circle in FIG. 5a. The lump/hill shapes are considered to be caused by the top organic transistor having a high positive threshold voltage turning on.

The shift in the above transfer curve can account for a body effect in the silicon transistor. In a bulk device, a body effect is defined as dependency of threshold voltage on substrate bias voltage. Similarly, in the dual-gate organic transistor structure according to this exemplary embodiment, the body effect can be defined as dependency of the threshold voltage of the bottom gate organic transistor on the top gate bias voltage. The dependency of the threshold voltage on the top gate bias voltage can be expressed by the following Equation 1:

$$\frac{d {V}_{th}}{d {V}_{G 2}} = - \frac{{C}_{pen} {C}_{par}}{{C}_{ox} ( {C}_{pen} + {C}_{par} )} ≅ - \frac{{C}_{par}}{{C}_{ox}} , \qquad Equation 1$$

where Cox, Cpen and Cpar are capacitances of the bottom gate dielectric (Al₂O₃), the organic semiconductor (pentacene), and the top gate dielectric (parylene), respectively.

While an additional level shifter has been conventionally used to control the location of an inversion voltage Vᵢₙᵥₑᵣₛᵢₒₙ, the present invention eliminates the need for a level shifter by using a dual-gate driver transistor structure.

As shown in FIG. 5b, a slope of −0.53 is obtained dividing change in the threshold voltage dVₜₕ by change in the top gate bias voltage dV_{G2} measured at the dual-gate organic transistor having parylene of a 300 nm thickness. This value differs from a theoretical Cpar/Cox value, −0.17. This difference between the value induced from the dual-gate organic transistor having a parylene of a 300 nm thickness and the theoretical value is caused by influence from deformation of a transfer curve, e.g., deformation such as the lump/hill shapes of FIG. 5a and negative bias voltage stress. However, by applying a parylene of a 1000 nm thickness, a slope of about −0.048 was obtained. This value is substantially consistent with a theoretical Cpar/Cox value, −0.052.

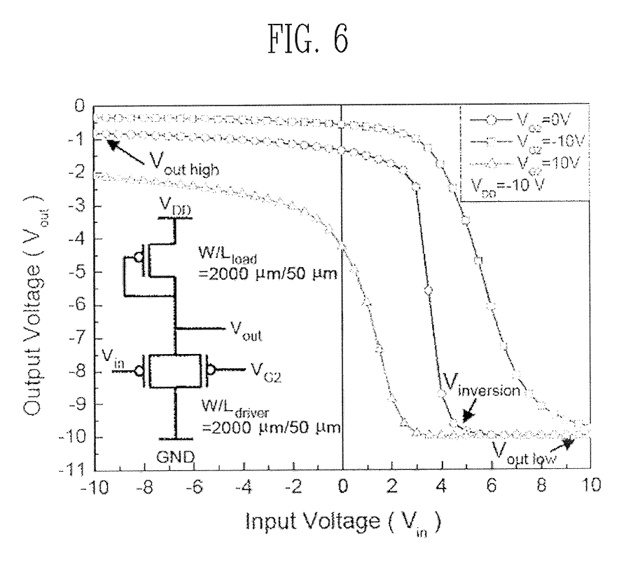

FIG. 6 illustrates a circuit of a D-inverter fabricated with a dual-gate organic transistor and its voltage transfer characteristic according to an exemplary embodiment of the present invention.

In this exemplary embodiment, a D-inverter composed of two organic transistors having W/L ratio=2000 nm/50 nm was fabricated. In a conventional D-inverter, the W/L ratio of a load transistor is greater than that of a driver transistor to obtain a depletion type load transistor. However, to implement the D-inverter according to the present invention, organic transistors having the same W/L ratio were used and a mode of the transistors having a dual-gate structure was changed.

FIG. 6 shows voltage transfer characteristics (VTCs) of a D-inverter composed of organic transistors having a dual-gate structure. The voltage transfer characteristics (VTCs) of the D-inverter show that a threshold voltage Vₜₕ of the driver transistor shifted to a positive zone when a top gate bias voltage V_{G2} of the driver transistor was −10V, and ON current increased, leading to a large positive inversion voltage Vᵢₙᵥₑᵣₛᵢₒₙ and a large swing range. When V_{G2}=10V, voltage transfer characteristics show that the threshold voltage Vₜₕ shifted to a negative zone, decreasing ON current, and the inversion voltage Vᵢₙᵥₑᵣₛᵢₒₙ shifted to a negative zone, decreasing ON current and swing range. In this manner, a low level output voltage Vₒᵤₜ is determined by a supply voltage, power voltage V_{dd}, and a high level output voltage Vₒᵤₜ is dependent on a threshold voltage Vₜₕ or ON current of the driver transistor. Further, the position of the inversion voltage Vᵢₙᵥₑᵣₛᵢₒₙ is dependent on the threshold voltage Vₜₕ of the driver transistor.

In the D-inverter, the driver transistor needs to have a negative threshold voltage and the load transistor needs to have a positive threshold voltage to act as a circuit building unit. In the present invention, the driver transistor is formed with a dual-gate structure and a positive bias voltage is applied to the top gate so that a body effect appears in the organic semiconductor. Accordingly, the threshold voltage is shifted to a negative zone due to positive potential at the top gate of the driver transistor, so that the driver transistor acts as an enhancement type transistor. In this manner, the inverter can be easily implemented with a dual-gate organic transistor.

Further, according to the present invention, a dual-gate organic transistor structure can be applied to an organic inverter, and a threshold voltage and ON current of the transistor can be controlled so that the transistor functions as a level shifter. In addition, passivation performance can be improved by using a top gate dielectric parylene and a top gate electrode on an organic channel active layer of the dual-gate organic transistor. In this manner, the shelf-life of the dual-gate organic transistor can be lengthened and the stability and passivation performance of the inverter can be improved.

Meanwhile, in the above-described exemplary embodiments, it may be preferable for the inverter to be implemented with an organic transistor having a bottom contact structure, in light of actual organic transistor fabrication, mass production and inverter integration. On the other hand, it may be preferable for the inverter to be implemented with an organic transistor having a top contact structure, in the light of the characteristics, particularly mobility, of the organic transistor.

As described above, according to the present invention, it is possible to increase the lifespan and improve the reliability of the device. It is also possible to provide an organic inverter in which characteristics of organic electronic elements can be easily adjusted according to circuit design, even after fabricating the organic electronic elements.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. An inverter comprising:
a load transistor; and
a driver transistor connected to the load transistor and having a dual-gate structure and an organic channel.

2. The inverter according to claim 1, wherein the driver transistor comprises:
a bottom gate electrode facing the organic channel with a first dielectric layer interposed therebetween;
a top gate electrode facing the organic channel with a second dielectric layer interposed therebetween; and
source and drain electrodes connected to the organic channel.

3. The inverter according to claim 2, wherein the load transistor uses the first dielectric layer or the second dielectric layer as a gate insulating layer.

4. The inverter according to claim 2, wherein a positive bias voltage is applied to the top gate electrode.

5. The inverter according to claim 4, wherein the load transistor has a gate and a source connected to each other.

6. The inverter according to claim 4, wherein the load transistor has a gate and a drain connected to each other.

7. The inverter according to claim 1, wherein the driver transistor and the load transistor have the same W/L ratio.

8. An inverter comprising:
a load transistor having a dual-gate structure and an organic channel; and
a driver transistor connected to the load transistor.

9. The inverter according to claim 8, wherein the load transistor comprises:
a bottom gate electrode facing the organic channel with a first dielectric layer interposed therebetween;
a top gate electrode facing the organic channel with a second dielectric layer interposed therebetween; and
source and drain electrodes connected to the organic channel.

10. The inverter according to claim 9, wherein the driver transistor uses the first dielectric layer or the second dielectric layer as a gate insulating layer.

11. The inverter according to claim 9, wherein a negative bias voltage is applied to the top gate electrode.

12. The inverter according to claim 9, wherein a positive bias voltage is applied to the top gate electrode.

13. The inverter according to claim 11, wherein the load transistor has a gate and a source connected to each other.

14. The inverter according to claim 12, wherein the load transistor has a gate and a source connected to each other.

15. The inverter according to claim 11, wherein the load transistor has a gate and a drain connected to each other.

16. The inverter according to claim 12, wherein the load transistor has a gate and a drain connected to each other.

17. The inverter according to claim 8, wherein the driver transistor and the load transistor have the same W/L ratio.

18. An inverter comprising:
a load transistor having a dual-gate structure and an organic channel; and
a driver transistor having a dual-gate structure and an organic channel and connected to the load transistor.

19. The inverter according to claim 18, wherein each of the load transistor and the driver transistor comprises
a bottom gate electrode facing the organic channel with a first dielectric layer interposed therebetween;
a top gate electrode facing the organic channel with a second dielectric layer interposed therebetween; and
source and drain electrodes connected to the organic channel.

20. The inverter according to claim 19, wherein the load transistor has a gate and a source connected to each other.

21. The inverter according to claim 20, wherein a positive bias voltage is applied to the top gate electrode of the driver transistor, and a negative bias voltage is applied to the top gate electrode of the load transistor.

22. The inverter according to claim 19, wherein the load transistor has a gate and a drain connected to each other.

23. The inverter according to claim 22, wherein a positive bias voltage is applied to top gate electrodes of both the load transistor and the driver transistor.

24. The inverter according to claim 18, wherein the driver transistor and the load transistor have the same W/L ratio.
